(19) United States
(12) Patent Application Publication
(10) Pub. No.: US 2026/0011372 A1
(43) Pub. Date: Jan. 8, 2026

(54) MEMORY DEVICE AND METHOD OF PERFORMING PROGRAM OPERATION THEREOF

(71) Applicant: SK hynix Inc., Gyeonggi-do (KR)

(72) Inventors: Jae Woong KIM, Gyeonggi-do (KR); In Su PARK, Gyeonggi-do (KR); Jung Shik JANG, Gyeonggi-do (KR); Dong Jae JUNG, Gyeonggi-do (KR); Young Hwa JO, Gyeonggi-do (KR); Jung Dal CHOI, Gyeonggi-do (KR)

(21) Appl. No.: 19/257,479

(22) Filed: Jul. 2, 2025

(30) Foreign Application Priority Data
Jul. 3, 2024 (KR) 10-2024-0087637
Dec. 26, 2024 (KR) 10-2024-0197041

(51) Int. Cl. G11C 16/10; G11C 16/34

(52) U.S. Cl. CPC G11C 16/10; G11C 16/3459

(57) ABSTRACT

Embodiments of the present disclosure relate to a memory device including a memory cell array including a plurality of memory cells, a peripheral circuit performing a program operation including a plurality of program loops, each program loop including a program pulse application operation and a verify operation, and a control logic circuit controlling the peripheral circuit so that fixed program pulses having a constant voltage level are applied to memory cells having a same target threshold voltage during the plurality of program loops, and a program inhibition voltage is applied to memory cells determined based on a result of the verify operation during the program pulse application operation.

### CROSS-REFERENCE TO RELATED APPLICATION

The present application claims priorities under 35 U.S.C. § 119(a) to Korean patent application number 10-2024-0087637 filed on Jul. 3, 2024, and Korean patent application number 10-2024-0197041 field on Dec. 26, 2024, the entire disclosures of which are incorporated by reference herein.

### BACKGROUND

### 1. Technical Field

Various embodiments of the present disclosure relate generally to a memory device, and more particularly, to a memory device and a method of performing a program operation to increase threshold voltages of memory cells to target threshold voltages by applying fixed program pulses to the memory cells having the same target threshold voltage during a plurality of program loops.

### 2. Related Art

Memory devices are divided into volatile memory devices and non-volatile memory devices. Volatile memory devices store data only when power is supplied, and the stored data disappears when the power supply is cut off. On the other hand, the data does not disappear in non-volatile memory devices even when power is cut off.

A memory device may perform a program operation by applying program pulses to memory cells. As the number of threshold voltage distributions of the memory cells increases, the threshold voltage distributions of the memory cells need to be more narrowed. When target threshold voltages of the memory cells are different, the time required for the program operation may vary for each memory cell. First, a retention phenomenon may occur in which threshold voltage distributions of memory cells whose threshold voltages reach the target threshold voltages becomes wider over time.

### SUMMARY

According to embodiments of the present disclosure, a memory device and a method of performing a program operation improve a threshold voltage distribution of memory cells by applying fixed program pulses to memory cells according to a verify operation performed on the memory cells earlier than an operation of applying a program pulse during a program operation, and completing the program operation of the memory cells in a same program loop.

According to an embodiment of the present disclosure, a memory device may include a memory cell array including a plurality of memory cells, a peripheral circuit performing a program operation including a plurality of program loops, each program loop including a program pulse application operation and a verify operation, the program pulse application operation including applying program pulses to the plurality of memory cells to increase threshold voltages of the plurality of memory cells, the verify operation including detecting whether the threshold voltages of the plurality of the memory cells reach target levels before performing the program pulse application operation, and a control logic circuit controlling the peripheral circuit so that fixed program pulses having a constant voltage level are applied to memory cells having a same target threshold voltage during the plurality of program loops, and a program inhibition voltage is applied to memory cells determined based on a result of the verify operation during the program pulse application operation.

According to an embodiment of the present disclosure, a method of operating a memory device includes performing a first verify operation included in an Nth program loop among a plurality of program loops, each program loop including a program pulse application operation and a verify operation, the program pulse application operation including applying program pulses to a plurality of memory cells to increase threshold voltages of the plurality of memory cells, the verify operation including detecting whether the threshold voltages of the plurality of memory cells reach target levels; determining memory cells to which a program inhibition voltage is to be applied among the plurality of memory cells, based on a result of the first verify operation and target threshold voltages of the plurality of memory cells, when a first program pulse application operation included in the Nth program loop is performed; and performing the first program pulse application operation by applying the program inhibition voltage according to a result of determination, wherein, during the plurality of program loops, the program pulses applied to memory cells having a same target threshold voltage are fixed program pulses having a constant voltage level.

### BRIEF DESCRIPTION OF THE DRAWINGS

FIG. 1 is a diagram illustrating a memory device according to an embodiment of the present disclosure;

FIG. 2 is a diagram for describing a program operation performed by applying fixed program pulses to memory cells having the same target threshold voltage;

FIG. 3 is a diagram illustrating a program operation according to an embodiment of the present disclosure;

FIG. 4 is a diagram illustrating a program operation according to another embodiment of the present disclosure;

FIG. 5 is a diagram for describing an overhead time generated during a program operation;

FIG. 6 is a diagram illustrating a method of reducing an overhead time according to an embodiment of the present disclosure;

FIG. 7 is a diagram illustrating a method of reducing an overhead time according to another embodiment of the present disclosure;

FIG. 8 is a flowchart illustrating a program operation according to an embodiment of the present disclosure; and

FIG. 9 is a diagram exemplarily illustrating a data storage system including a memory system according to an embodiment of the present disclosure.

### DETAILED DESCRIPTION

Specific structural or functional descriptions of embodiments in accordance with concepts which are disclosed in this specification are illustrated only to describe the embodiments. The embodiments may be carried out by various forms but the descriptions are not limited to the embodiments described in this specification.

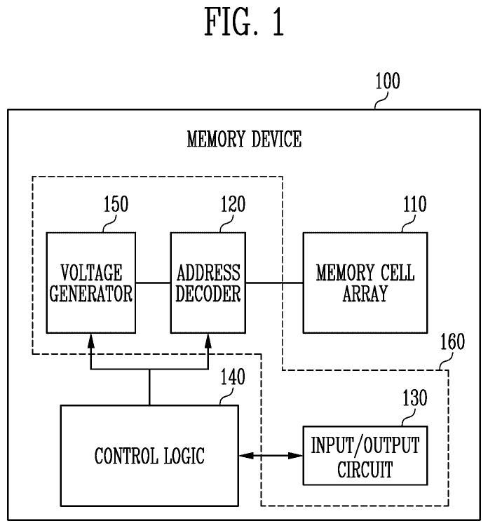

FIG. 1 is a diagram illustrating a memory device 100 according to an embodiment of the present disclosure.

Referring to FIG. 1, the memory device 100 may store data. The memory device 100 may include a memory cell array 110 including memory cells storing data, an address decoder 120 decoding a column address, an input and output (input/output) circuit 130 transmitting and receiving data to and from the outside of the memory device 100, a control logic circuit 140, and a voltage generator 150 generating a plurality of voltages having various voltage levels.

Each of the memory cells included in the memory cell array 110 may be a single-level cell (SLC) which stores one bit of data or a memory cell which stores multi-bit data. A memory cell storing multi-bit data may be a multi-level cell (MLC) storing two bits of data, a triple-level cell (TLC) storing three bits of data, a quad-level cell (QLC) storing four bits of data, or a penta-level cell (PLC) storing five bits of data, depending on the number of bits of the multi-bit data.

The address decoder 120 may be coupled to the memory cell array 110 through word lines. The address decoder 120 may decode an address received from the input/output circuit 130 to select a word line. The address decoder 120 may apply a voltage received from the voltage generator 150 to the selected word line. The address decoder 120 may operate in response to a control signal received from the control logic circuit 140.

The input/output circuit 130 may include page buffers which read and temporarily store data stored in memory cells. The input/output circuit 130 may output the data stored in the page buffers to the outside of the memory device 100, or may store data received from the outside in the page buffers and store the data in the memory cells.

The page buffers may be coupled to the memory cells through bit lines, and may store sensing data obtained by sensing threshold voltages of the memory cells during a read operation or a program operation. The sensing data may be transferred to the control logic circuit 140.

The control logic circuit 140 may control various operations of the memory device 100. The control logic circuit 140 may generate control signals to control the address decoder 120, the input/output circuit 130, and the voltage generation circuit 150 to perform read, program, and erase operations on the memory cell array 110.

The control logic circuit 140 may determine whether the program operation fails or whether the verify operation passes, based on the sensing data received from the input/output circuit 130. More specifically, when a threshold voltage of a memory cell is greater than a verify voltage, the control logic circuit 140 may determine that the verify operation is a verify pass. The control logic circuit 140 may determine that the program operation is a program pass when the number of verify pass memory cells is greater than or equal to a reference value.

The voltage generator 150 may generate voltages necessary for the operation of the memory device 100. The voltage generator 150 may include voltage regulators which generate voltages having various potentials. The voltage generator 150 may generate a program voltage, a verify voltage, and a read voltage required by the memory device 100. The voltages generated by the voltage generator 150 may be supplied to the memory cells included in the memory cell array 110 through the address decoder 120.

In an embodiment of the present disclosure, the address decoder 120, the input/output circuit 130, and the voltage generator 150 may be referred to as a peripheral circuit 160. The control logic circuit 140 may control the peripheral circuit 160 such that operations may be performed on the memory cells included in memory cell array 110.

In an embodiment of the present disclosure, the control logic circuit 140 may control the peripheral circuit 160 so that a program operation on the memory cells may be performed. The peripheral circuit 160 may perform a program pulse application operation of applying a program pulse to the memory cells to increase threshold voltages and a verify operation of detecting whether the threshold voltages of the memory cells have reached target levels.

The control logic circuit 140 may maintain a constant voltage level of program pulses which are applied to memory cells having the same target threshold voltage when a plurality of program loops including a program pulse application operation and a verify operation are performed. The program pulses having the constant voltage level which are applied to the memory cells during the plurality of program loops may be referred to as fixed program pulses.

The control logic circuit 140 may first perform a verify operation on the memory cells before applying the fixed program pulse to the memory cells. The control logic circuit 140 may control the peripheral circuit 160 to apply a program inhibition voltage to memory cells having threshold voltages greater than target threshold voltages according to a result of the verify operation. The result of the verify operation may be stored in the page buffers included in the input/output circuit 130. In some embodiments, data indicating the verify pass or verify fail of the memory cells may be stored in latch circuits included in the page buffers.

The control logic 140 may reset the page buffers which store a result of a verify operation performed in a previous program loop before a verify operation included in each of the plurality of program loops is performed. In response to the resetting of the page buffers, the latch circuits in which the data indicating the verify pass or the verify fail of the memory cells were stored may be initialized.

A verify operation performed before fixed program pulses are applied may be performed on every memory cell which is subject to a program operation. All memory cells subject to a program operation include memory cells which have already passed verification and memory cells which have not yet passed verification.

The control logic circuit 140 may apply a plurality of fixed program pulses and a plurality of verify voltages to the memory cells while a single program loop is being performed. The control logic circuit 140 may set an order of applying the plurality of fixed program pulses and the plurality of verify voltages based on magnitudes of the target threshold voltages of the memory cells.

According to an embodiment of the present disclosure, a program operation of all memory cells coupled to the selected word line is completed in the same program loop, so that a retention phenomenon caused by a difference in the time at which a threshold voltage reaches a target level may be reduced. As a result, a threshold voltage distribution of the memory cells may be kept narrow.

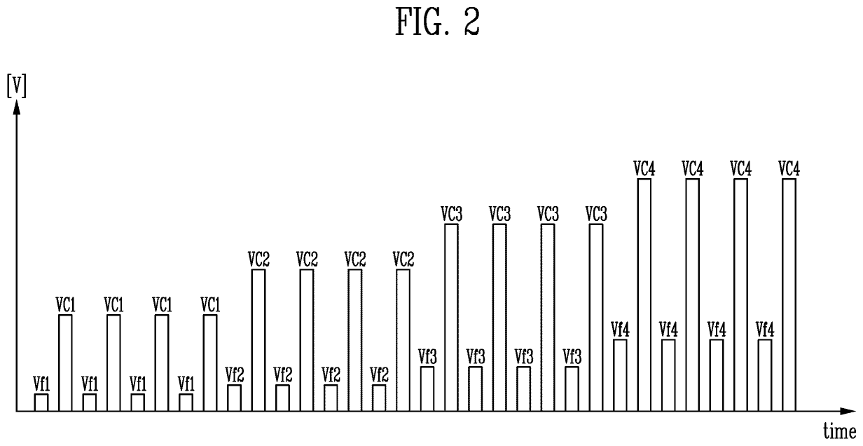

FIG. 2 is a diagram for describing a program operation performed by applying fixed program pulses to memory cells having the same target threshold voltage.

Referring to FIG. 2, fixed program pulses having a constant voltage level may be applied to memory cells having the same target threshold voltage during a plurality of program loops. A verify operation may be performed on the memory cells before the fixed program pulses are applied. In FIG. 2, the horizontal axis represents time and the vertical axis represents the magnitude of the pulse. For convenience, in FIG. 2 and below, a memory cell is an MLC in which two bits of data is stored in one memory cell, and four fixed program pulses are applied so that threshold voltages of the memory cells reach target levels.

A plurality of memory cells coupled to a selected word line may be programmed in ascending order of target threshold voltages, i.e., from a lowest target threshold voltage to a highest target threshold voltage. First fixed program pulses VC1 are applied to first memory cells whose target threshold voltages are at a first level, second fixed program pulses VC2 are applied to second memory cells whose target threshold voltages are at a second level, third fixed program pulses VC3 are applied to third memory cells whose target threshold voltages are a third level, and fourth fixed program pulses VC4 are applied to fourth memory cells whose target threshold voltages are at a fourth level. Here, the fourth level is greater than the third level, the third level is greater than the second level, and the second level is greater than the first level.

The control logic circuit 140 may control the peripheral circuit 160 such that a first verify voltage Vf1 may be applied before the first fixed program pulses VC1 are applied, and a second verify voltage Vf2 may be applied before the second fixed program pulses VC2 are applied. Similarly, the control logic circuit 140 may control the peripheral circuit 160 such that a third verify voltage Vf3 may be applied before the third fixed program pulses VC3 are applied, and a fourth verify voltage Vf4 may be applied before the fourth fixed program pulses VC4 are applied.

When the fixed program pulse is applied four times, the control logic circuit 140 may determine a program pass or a program fail based on the number of memory cells whose threshold voltages reach the target levels. In FIG. 2, the first memory cells are the first to program pass, and the fourth memory cells are the last to program pass. Since the first memory cells are in a standby state until the second, third, and fourth memory cells pass program verification, a retention phenomenon in which the threshold voltage distribution becomes wider may occur. Since memory cells having the same target threshold voltage are programmed with each other, as the number of target threshold voltages increases, the likelihood of a retention phenomenon occurring in memory cells programmed first may increase.

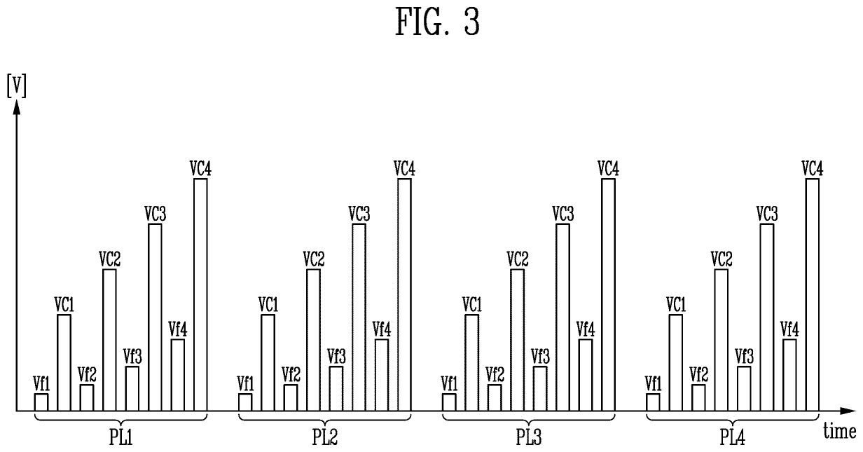

FIG. 3 is a diagram illustrating a program operation according to an embodiment of the present disclosure.

Referring to FIG. 3, a plurality of fixed program pulses and verify voltages may be applied to memory cells when one program loop is performed. The part corresponding to the description of FIG. 2 may be omitted from the description of FIG. 3. In FIG. 3 and below, the first, second, third, and fourth verify voltages Vf1, Vf2, Vf3, and Vf4 and the first, second, third, and fourth fixed program pulses VC1, VC2, VC3, and VC4 are applied to the memory cells in one program loop, and the program operation includes four program loops.

The control logic circuit 140 may control the peripheral circuit 160 so that a first program loop PL1 may be performed. A first verify operation may be performed on the first memory cells by applying the first verify voltage Vf1 to the memory cells. Memory cells to which a program inhibition voltage is to be applied may be determined among the memory cells based on a result of the first verify operation. The control logic circuit 140 may apply the program inhibition voltage to the memory cells determined based on the result of the first verify operation when the first fixed program pulses VC1 are applied to the memory cells.

Similar to the first memory cells, the verify voltages and the fixed program pulses may be applied to the memory cells to increase the threshold voltages of the second, third, and fourth memory cells. In the first program loop PL1, the first, second, third, and fourth verify voltages Vf1, Vf2, Vf3, and Vf4 and the first, second, third, and fourth fixed program pulses VC1, VC2, VC3, and VC4 are applied. In the same manner, the first, second, third, and fourth verify voltages Vf1, Vf2, Vf3, and Vf4 and the first, second, third, and fourth fixed program pulses VC1, VC2, VC3, and VC4 are also applied to the memory cells in a second program loop PL2, a third program loop PL3, and a fourth program loop PL4.

The control logic circuit 140 may determine, based on the target threshold voltages, voltage levels of the fixed program pulses and the verify voltages corresponding to the target threshold voltages. For example, the control logic circuit 140 may determine voltage levels of the first verify voltage Vf1 and the first fixed program pulses VC1 based on the first level. In the same manner, the voltage levels of the second, third, and fourth verify voltages Vf2, Vf3, and Vf4 and the second, third, and fourth fixed program pulses VC2, VC3, and VC4 may be determined.

The control logic circuit 140 may set an order of applying the first, second, third, and fourth verify voltages Vf1, Vf2, Vf3, and Vf4 and the first, second, third, and fourth fixed program pulses VC1, VC2, VC3, and VC4 based on the magnitudes of the target threshold voltages. In FIG. 3, the application order may be set such that the verify voltages and the fixed program pulses may be applied in ascending order of the magnitudes of the target threshold voltages.

The program operation of the memory cells in FIG. 3 may be completed in the fourth program loop PL4. When the program operation on each of the first memory cells, the second memory cells, the third memory cells, and the fourth memory cells passes, the program operation on each of the first, second, third, and fourth memory cells is completed in the same program loop. Since the first memory cells which pass program verification wait for a short period of time until the remaining memory cells pass program verification, a retention phenomenon in which a threshold voltage distribution of the memory cells becomes wider may be reduced.

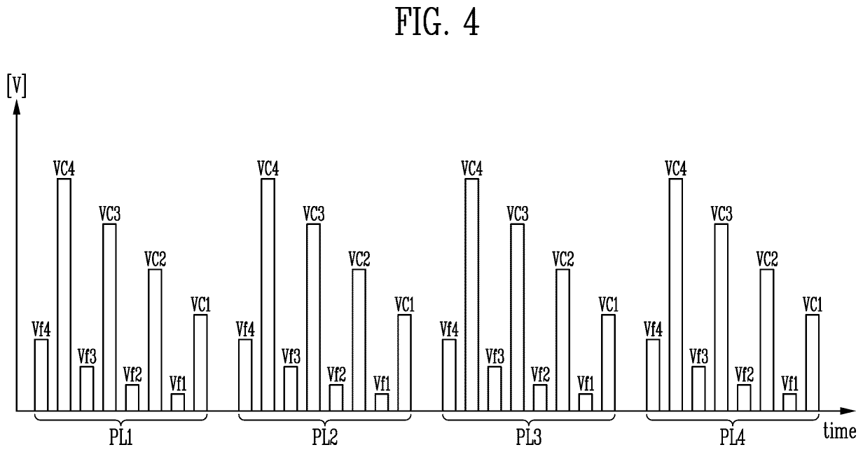

FIG. 4 is a diagram for describing a program operation according to another embodiment of the present disclosure.

Referring to FIG. 4, a plurality of fixed program pulses and a plurality of verify voltages may be applied to memory cells when one program loop is performed. The part of the description of FIG. 4 corresponding to the descriptions of FIGS. 2 and 3 may be omitted.

The control logic circuit 140 of FIG. 1 may set an order of applying the first, second, third, and fourth verify voltages Vf1, Vf2, Vf3, and Vf4 and the first, second, third, and fourth fixed program pulses VC1, VC2, VC3, and VC4 based on the magnitudes of the target threshold voltages. In FIG. 4, the order of application may be set such that the verify voltages and the fixed program pulses may be applied in descending order of the magnitudes of the target threshold voltages.

A fourth verify operation may be performed on the fourth memory cells by applying the fourth verify voltage Vf4 to the memory cells. Memory cells to which a program inhibition voltage is to be applied may be determined among the memory cells based on a result of the fourth verify operation. The control logic circuit 140 may apply the program inhibition voltage to the memory cells determined based on the result of the fourth verify operation when the fourth fixed program pulses VC4 are applied to the memory cells.

Like the fourth memory cells, the verify voltages and the fixed program pulses may be applied to the memory cells to increase the threshold voltages of the first memory cells, the second memory cells, and the third memory cells. In the first program loop PL1, the first, second, third, and fourth verify voltages Vf1, Vf2, Vf3, and Vf4 and the first, second, third, and fourth fixed program pulses VC1, VC2, VC3, and VC4 are applied in the determined order. In the second program loop PL2, the third program loop PL3, and the fourth program loop PL4, the first, second, third, and fourth verify voltages Vf1, Vf2, Vf3, and Vf4 and the first, second, third, and fourth fixed program pulses VC1, VC2, VC3, and VC4 are applied to the memory cells in the determined order.

In another embodiment of the present disclosure, the control logic circuit 140 may change the application order of the verify voltages and the fixed program pulses based on the retention characteristic of the threshold voltages. For example, unlike FIGS. 3 and 4, when the threshold voltages of the third memory cells are most vulnerable to retention, the control logic circuit 140 may set the application order of the third verify voltage Vf3 and the third fixed program pulses VC3 as the last. When the threshold voltages of the second memory cells are most robust to retention, the control logic circuit 140 may control the peripheral circuit 160 to apply the second verify voltage Vf2 and the second fixed program pulses VC2 first during a program loop.

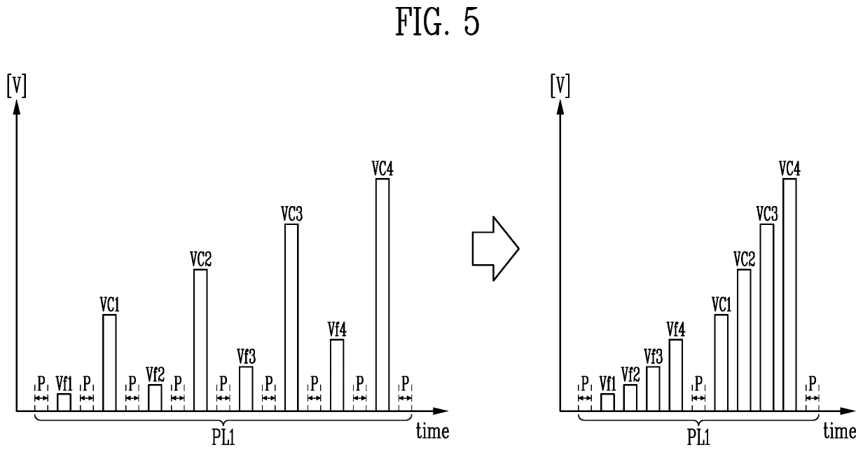

FIG. 5 is a diagram for describing an overhead time generated during a program operation.

Referring to FIG. 5, an overhead time which occurs between a verify operation and a program operation may be shown. FIG. 5 shows a method of reducing an overhead time P occurring during the first program loop PL1 of FIG. 3. For convenience, the program loop PL1 of FIG. 3 is described as an example, but the overhead time P may be reduced by applying verify voltages and fixed program pulses for each type.

According to the left illustration of FIG. 5, during the first program loop PL1, the overhead time P may occur 9 times. Since a preparation time for performing the first verify operation is required before the first verify voltage Vf1 is applied, the overhead time P occurs. The overhead time P also occurs when a verify operation is switched to a program pulse application operation. In FIG. 5, the overhead time P occurs at the beginning and the end of the first program loop PL1, and the overhead time P also occurs at the time of switching between the verify operation and the program pulse application operation.

As the overhead time P occurs, the time required to perform the program loop is increased. Even when the program operation ends in the same program loop, if the overhead time P occurs, a threshold voltage distribution of memory cells whose threshold voltages first reach the target levels may be deteriorated due to the retention phenomenon. In addition, as the time required for each program loop increases, the time required for the entire program operation also increases.

The threshold voltage distribution of the memory cells may be improved and the time required for the program operation may be reduced by reducing the occurrence of the overhead time P. The control logic circuit 140 may control the peripheral circuit 160 to reduce the number of switching times between the verify operation and the program pulse application operation.

According to the right illustration of FIG. 5, during a program loop, the control logic circuit 140 may control the peripheral circuit 160 to apply the first, second, third, and fourth verify voltages Vf1, Vf2, Vf3, and Vf4 to the memory cells prior to the first, second, third, and fourth fixed program pulses VC1, VC2, VC3, and VC4. Since the fixed program pulses are applied after the verify voltages are first applied to the memory cells, a single transition occurs from a verify operation to a program pulse application operation. The number of occurrences of the overhead time P may be reduced by 6 times for each program loop.

Since the total overhead time is reduced, the time required to perform the program loop is also reduced. Since the time required to perform the program loop is reduced, the threshold voltage distribution may not become wider by the retention. The threshold voltage distribution may be improved by applying the verify voltages to the memory cells before the fixed program pulses.

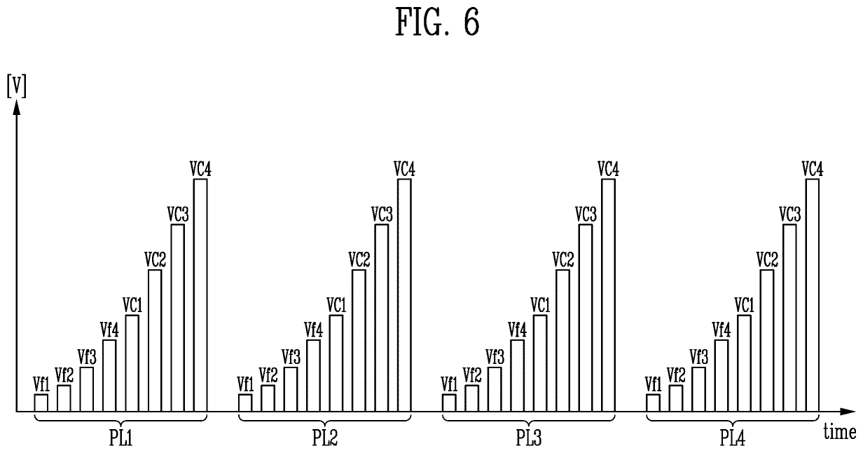

FIG. 6 is a diagram illustrating a method of reducing an overhead time according to an embodiment of the present disclosure.

Referring to FIG. 6, the program operation as shown in FIG. 3 may be performed according to the method described in FIG. 5. In FIG. 6 and below, the overhead time may not be shown for convenience. The first, second, third, and fourth verify voltages Vf1, Vf2, Vf3, and Vf4 may be applied to the memory cells prior to the first, second, third, and fourth fixed program pulses VC1, VC2, VC3, and VC4 when the program loops PL1, PL2, PL3, and PL4 are performed.

When performing the first program loop PL1, the control logic circuit 140 may control the peripheral circuit 160 so that the first, second, third, and fourth verify voltages Vf1, Vf2, Vf3, and Vf4 may be applied to the memory cells before the first, second, third, and fourth fixed program pulses VC1, VC2, VC3, and VC4. The second verify voltage Vf2 may be applied after the first verify voltage Vf1 is applied to the memory cells. The third and fourth verify voltages Vf3 and Vf4 may also be sequentially applied to the memory cells. The first, second, third, and fourth fixed program pulses VC1, VC2, VC3, and VC4 may also be sequentially applied after the first, second, third, and fourth verify voltages Vf1, Vf2, Vf3, and Vf4 are applied to the memory cells.

The first, second, third, and fourth verify voltages Vf1, Vf2, Vf3, and Vf4 may be applied to the memory cells prior to the first, second, third, and fourth fixed program pulses VC1, VC2, VC3, and VC4 when the second to fourth program loops PL2, PL3, and PL4 are performed.

When the program operation is performed according to the method shown in FIG. 6, the number of occurrences of the overhead time P is reduced by 24 times compared to the method shown in FIG. 3. Deterioration of the threshold voltage distribution due to the occurrence of the retention is prevented, and the total time required for the program operation may be reduced.

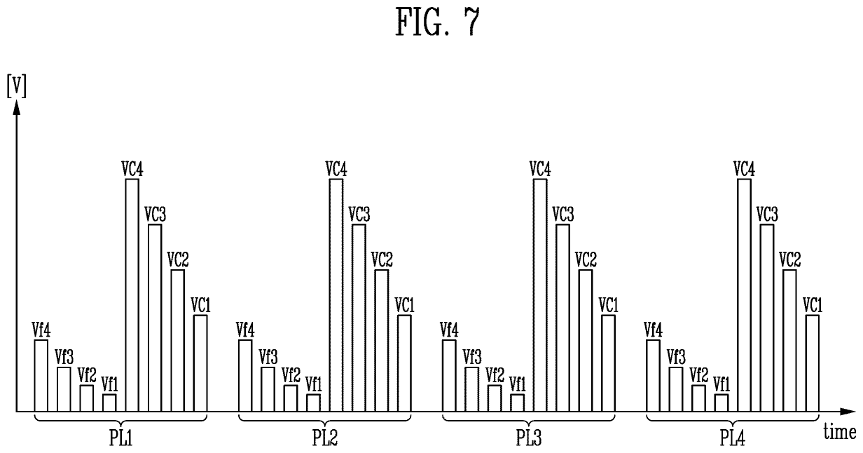

FIG. 7 is a diagram illustrating a method of reducing an overhead time according to another embodiment of the present disclosure.

Referring to FIG. 7, the program operation shown in FIG. 4 may be performed according to the method described in FIG. 5. The part corresponding to the description of FIG. 6 may be omitted from the descriptions of FIG. 7.

The control logic circuit 140 may control the peripheral circuit 160 to apply the first, second, third, and fourth verify voltages Vf1, Vf2, Vf3, and Vf4 to the memory cells in descending order of magnitudes of the target threshold voltages corresponding to these verify voltages. The third verify voltage Vf3 may be applied to the memory cells after the fourth verify voltage Vf4 is applied to the memory cells. Similarly, the first verify voltage Vf1 may be applied to the memory cells after the second verify voltage Vf2 is applied to the memory cells.

During the first program loop PL1, after the first, second, third, and fourth verify voltages Vf1, Vf2, Vf3, and Vf4 are applied to the memory cells, the first, second, third, and fourth fixed program pulses VC1, VC2, VC3, and VC4 may also be applied in descending order of the magnitudes of the target threshold voltages corresponding to the fixed program pulses. The third fixed program pulses VC3 may be applied to the memory cells after the fourth fixed program pulse VC4 is applied to the memory cells. Similarly, the first fixed program pulses VC1 may be applied to the memory cells after the second fixed program pulses VC2 are applied to the memory cells.

The first, second, third, and fourth verify voltages Vf1, Vf2, Vf3, and Vf4 may be applied to the memory cells prior to the first, second, third, and fourth fixed program pulses VC1, VC2, VC3, and VC4 when the second, third, and fourth program loops PL2, PL3, and PL4 are performed.

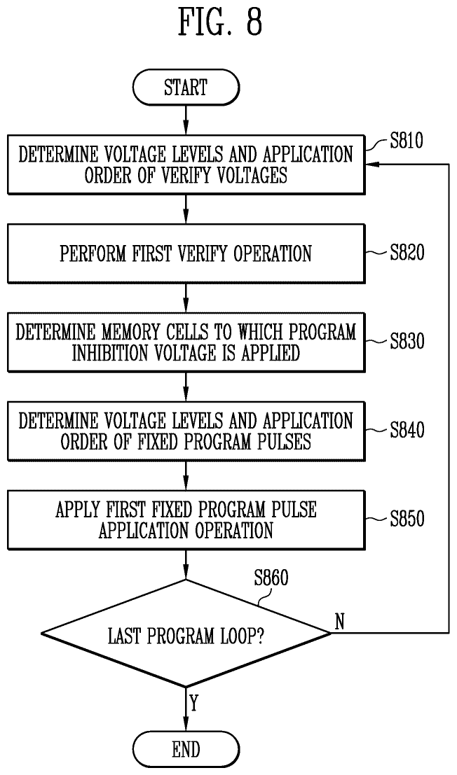

FIG. 8 is a flowchart illustrating a program operation according to an embodiment of the present disclosure.

Referring to FIG. 8, a memory device may perform a program operation including a plurality of program loops. Each program loop may include a program pulse application operation of applying program pulses to memory cells to increase threshold voltages of the memory cells, and a verify operation of detecting whether the threshold voltages of the memory cells reach target levels before the program pulse application operation is performed. The memory device may apply fixed program pulses having a constant voltage level to memory cells having the same target threshold voltage while the plurality of program loops are being performed, and may apply a program inhibition voltage to the memory cells determined based on a result of the verify operation while the program pulse application operation is being performed. According to an embodiment of the present disclosure, the threshold voltage distribution may be improved by setting an application order of the fixed program pulses and the verify voltages based on magnitudes of target threshold voltages.

At operation S810, the control logic circuit may determine voltage levels and application order of the verify voltages based on target threshold voltages of the memory cells. The control logic circuit may determine the order of application such that the verify voltages may be applied in ascending order of magnitudes of the target threshold voltages corresponding to the verify voltages. The control logic circuit may control the peripheral circuit to apply fixed program pulses after all verify voltages are applied.

At operation S820, the memory device may perform a first verify operation included in an Nth program loop. The memory device may apply the verify voltages to all of the memory cells to verify whether the threshold voltages reach the target threshold voltages. The memory cells to which the verify voltages are applied during the first verify operation may include both verify pass memory cells and verify fail memory cells, based on a result of the second verify operation included in an (N−1)th program loop.

At operation S830, the control logic circuit may determine memory cells to which a program inhibition voltage is to be applied, based on the result of the first verify operation and the target threshold voltages of the memory cells. The control logic circuit may determine memory cells whose threshold voltages are greater than the target threshold voltages corresponding to the fixed program pulses being applied as the memory cells to which the program inhibition voltage is to be applied.

At operation S840, the control logic circuit may determine the voltage levels and application order of the fixed program pulses based on the target threshold voltages. The control logic circuit may determine the application order such that fixed program pulses corresponding to smaller magnitudes of the target threshold voltages may be applied to the memory cells before the fixed program pulses corresponding to larger magnitudes of the target threshold voltages.

At operation S850, the memory device may perform a first fixed program pulse application operation included in the Nth program loop. The memory device may apply the fixed program pulses to the memory cells to increase the threshold voltages.

At operation S860, the control logic circuit may determine whether the Nth program loop being performed is the last program loop. Whether the Nth program loop is the last loop may be determined based on the number of times the fixed program pulses are applied. When the number of fixed program pulses applied is less than or equal to a reference value, it is determined that the Nth program loop is not the last program loop.

When the Nth program loop is not the last loop, the (N+1)th program loop may start to perform operations S810 to S860 again. When the number of fixed program pulses applied reaches the reference value, it is determined that the Nth program loop is the last program loop. The control logic circuit may determine whether the program operation fails based on the number of memory cells whose threshold voltages reach the target levels before the end of the last program loop.

The description of each of the steps of FIG. 8 may correspond to those of FIGS. 1 to 7.

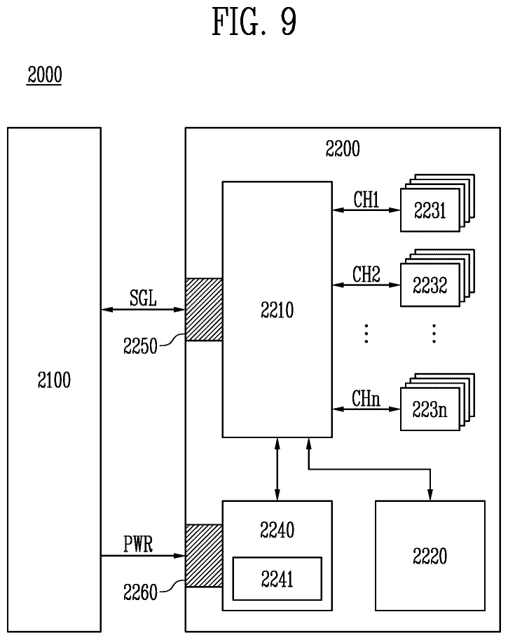

FIG. 9 is a diagram illustrating a data storage system 2000 including a memory system according to an embodiment of the present disclosure.

Referring to FIG. 9, the data storage system 2000 may include a host device 2100 and an SSD 2200.

The SSD 2200 may include a controller 2210, a buffer memory device 2220, nonvolatile memories 2231 to 223n, a power supply 2240, a signal connector 2250, and a power connector 2260.

The buffer memory device 2220 may temporarily store data to be stored in the plurality of nonvolatile memories 2231 to 223n. In addition, the buffer memory device 2220 may temporarily store data read from the nonvolatile memories 2231 to 223n. The data temporarily stored in the buffer memory device 2220 may be transferred to the host device 2100 or the nonvolatile memories 2231 to 223n in response to control of the controller 2210.

The nonvolatile memories 2231 to 223n may serve as storage media of the SSD 2200. The nonvolatile memories 2231 to 223n may be coupled to the controller 2210 through a plurality of channels CH1 to CHn, respectively. One or more nonvolatile memories may be coupled to one channel. Nonvolatile memories coupled to one channel may be coupled to the same signal bus or data bus.

The controller 2210 may perform operations of the SSD 2200. According to an embodiment of the present disclosure, the controller 2210 may control the SSD 2200 to perform a program operation including a plurality of program loops. Each program loop may include a program pulse application operation of applying program pulses to a plurality of memory cells to increase threshold voltages of the plurality of memory cells, and a verify operation of detecting whether the threshold voltages of the plurality of the memory cells reach target levels before performing the program pulse application operation. The controller 2210 may control the SSD 2200 such that fixed program pulses having a constant voltage level may be applied to memory cells having the same target threshold voltage while a plurality of program loops are being performed, and a program inhibition voltage may be applied to memory cells determined based on a result of a verify operation while a program pulse application operation is being performed. The controller 2210 may set an order of applying the verify voltages and the fixed program pulses corresponding to the target threshold voltages of the plurality of memory cells, respectively, based on magnitudes of the target threshold voltages. Accordingly, the time required for the program operation is reduced and the generation of retention is suppressed, so that threshold voltage distributions of the nonvolatile memories 2231 to 223n may be improved.

The power supply 2240 may supply power PWR which is input through the power connector 2260 to the inside of the SSD 2200. The power supply 2240 may include an auxiliary power supply 2241. The auxiliary power supply 2241 may supply power such that the SSD 2200 may be terminated normally when a sudden power off occurs. The auxiliary power supply 2241 may include large-capacity capacitors which charge the power PWR.

The controller 2210 may exchange signals SGL with the host device 2100 through the signal connector 2250. The signals SGL may include commands, addresses, and data. The signal connector 2250 may be configured as various types of connectors according to an interfacing method of the host device 2100 and the SSD 2200.

According to the embodiments of the present disclosure, a memory device and a method of performing a program operation apply fixed program pulses and verify voltages respectively corresponding to target threshold voltages during a program loop, thereby terminating a program operation of memory cells in the same program loop to improve a threshold voltage distribution degradation of the memory cells.

It will be apparent to those skilled in the art that various modifications can be made to the above-described embodiments without departing from the spirit or scope of the present disclosure. Thus, it is intended that the embodiments cover all such modifications provided they come within the scope of the appended claims and their equivalents. Furthermore, the embodiments may be combined to form additional embodiments.

What is claimed is:

1. A memory device comprising:
a memory cell array including a plurality of memory cells;
a peripheral circuit performing a program operation including a plurality of program loops, each program loop including a program pulse application operation and a verify operation, the program pulse application operation including applying program pulses to the plurality of memory cells to increase threshold voltages of the plurality of memory cells, the verify operation including detecting whether the threshold voltages of the plurality of the memory cells reach target levels before performing the program pulse application operation; and
a control logic circuit controlling the peripheral circuit so that fixed program pulses having a constant voltage level are applied to memory cells having a same target threshold voltage during the plurality of program loops, and a program inhibition voltage is applied to memory cells determined based on a result of the verify operation during the program pulse application operation.

2. The memory device of claim 1, wherein the control logic circuit determines voltage levels of the fixed program pulses and verify voltages corresponding to target threshold voltages of the plurality of memory cells, respectively, based on the target threshold voltages.

3. The memory device of claim 2, wherein the control logic circuit controls the peripheral circuit to apply i verify voltages and i fixed program pulses in an Nth program loop among the plurality of program loops in response to i target threshold voltages.

4. The memory device of claim 3, wherein the control logic circuit controls the peripheral circuit such that the i fixed program pulses are applied to the plurality of memory cells after the i verify voltages are all applied.

5. The memory device of claim 3, wherein the control logic circuit sets an order of the i verify voltages and the i fixed program pulses applied to the plurality of memory cells based on magnitudes of the i target threshold voltages corresponding to the i verify voltages.

6. The memory device of claim 3, wherein the control logic circuit sets an order of the i verify voltages and the i fixed program pulses applied to the plurality of memory cells based on magnitudes of the i target threshold voltages corresponding to the i fixed program pulses.

7. The memory device of claim 5, wherein the control logic circuit controls the peripheral circuit to apply the i verify voltages and the i fixed program pulses to the plurality of memory cells in descending order of the magnitudes of the i target threshold voltages corresponding thereto.

8. The memory device of claim 5, wherein the control logic circuit controls the peripheral circuit to apply the i verify voltages and the i fixed program pulses to the plurality of memory cells in ascending order of the magnitudes of the i target threshold voltages corresponding thereto.

9. The memory device of claim 3, wherein the control logic circuit controls the peripheral circuit so that a first verify operation included in the Nth program loop is performed independently of a result of a second verify operation included in an (N−1)th program loop.

10. The memory device of claim 9, wherein the control logic circuit controls the peripheral circuit to perform the first verify operation on both verify pass memory cells and verify fail memory cells based on the second verify operation.

11. The memory device of claim 10, wherein the control logic circuit controls the peripheral circuit to apply the program inhibition voltage to memory cells whose threshold voltages are greater than the i target threshold voltages corresponding to the i fixed program pulses being applied when the i fixed program pulses are applied.

12. A method of operating a memory device, the method comprising:
performing a first verify operation included in an Nth program loop among a plurality of program loops, each program loop including a program pulse application operation and a verify operation, the program pulse application operation including applying program pulses to a plurality of memory cells to increase threshold voltages of the plurality of memory cells, the verify operation including detecting whether the threshold voltages of the plurality of memory cells reach target levels;
determining memory cells to which a program inhibition voltage is to be applied among the plurality of memory cells, based on a result of the first verify operation and target threshold voltages of the plurality of memory cells, when a first program pulse application operation included in the Nth program loop is performed; and
performing the first program pulse application operation by applying the program inhibition voltage according to a result of determination,
wherein, during the plurality of program loops, the program pulses applied to memory cells having a same target threshold voltage are fixed program pulses having a constant voltage level.

13. The method of claim 12, wherein performing the first verify operation comprises:
determining voltage levels of i verify voltages corresponding to i target threshold voltages, respectively, when the number of target threshold voltages is i; and
verifying whether the threshold voltages reach the i target threshold voltages by applying the i verify voltages to all of the plurality of memory cells.

14. The method of claim 13, wherein the plurality of memory cells include both verify pass memory cells and verify fail memory cells based on a result of a second verify operation included in an (N−1)th program loop.

15. The method of claim 13, wherein verifying further comprises determining an order of applying the i verify voltages, based on magnitudes of the i target threshold voltages corresponding to the i verify voltages.

16. The method of claim 13, wherein determining the memory cells to which the program inhibition voltage is to be applied comprises:
determining voltage levels of i fixed program pulses corresponding to the i target threshold voltages, respectively, when the number of target threshold voltages is i; and
determining memory cells whose threshold voltages are greater than the i target threshold voltages corresponding to the i fixed program pulses being applied as the memory cells to which the program inhibition voltage is to be applied.

17. The method of claim 16, wherein performing the first program pulse application operation comprises determining an order of applying the i fixed program pulses based on magnitudes of the i target threshold voltages corresponding to the i fixed program pulses.

18. The method of claim 17, wherein the i fixed program pulses are applied in descending order of the magnitudes of the i target threshold voltages corresponding to the i fixed program pulses.

19. The method of claim 17, wherein the i fixed program pulses are applied in ascending order of the magnitudes of the i target threshold voltages corresponding to the i fixed program pulses.
